(19) United States
(12) Patent Application Publication
(10) Pub. No.: US 2022/0385792 A1
(43) Pub. Date: Dec. 1, 2022

(54) LENS MODULE AND ELECTRONIC DEVICE HAVING THE LENS MODULE

(71) Applicant: TRIPLE WIN TECHNOLOGY(SHENZHEN) CO.LTD., Shenzhen (CN)

(72) Inventor: FEI-FAN YU, Shenzhen (CN)

(21) Appl. No.: 17/534,703

(22) Filed: Nov. 24, 2021

(30) Foreign Application Priority Data
May 25, 2021 (CN) 202121129248.X

(51) Int. Cl. H04N 5/225; G02B 7/02; H05K 1/18

(52) U.S. Cl. CPC H04N 5/2254; G02B 7/025; H05K 1/183; H05K 2201/10151; H05K 2201/10121

(57) ABSTRACT

A lens module includes a holder, at least one lens, a base, a sensor, an anisotropic conductive film, a flexible circuit board, and a filling member. The filling member is arranged at a side of the sensor and received in the holder. Along a direction of an optical axis of the lens module, a distance between the side of the sensor and the anisotropic conductive film is defined as a first value, a thickness of the filling member is defined as a second value, a ratio of the second value to the first value is in a range of 0.8 to 1. An electronic device having the lens module is also provided.

### FIELD

The subject matter herein generally relates to a lens module and an electronic device having the lens module.

### BACKGROUND

Most lens modules include a lens, a lens holder, a filter, a photosensitive chip, a base, and a flexible circuit board. The lens is installed in the lens holder, the lens holder and the photosensitive chip are installed on the circuit board, and the filter is installed above the photosensitive chip. The photosensitive chip and the filter are received in the base. However, when the lens module undergoes a high temperature and high pressure test, the flexible circuit board is easy to be deformed.

Therefore, there is room for improvement within the art.

### BRIEF DESCRIPTION OF THE DRAWINGS

Implementations of the present disclosure will now be described, by way of embodiments, with reference to the attached figures.

FIG. 1 is a cross-sectional view of an embodiment of a lens module according to the present disclosure.

FIG. 2 is a cross-sectional view of another embodiment of a lens module according to the present disclosure.

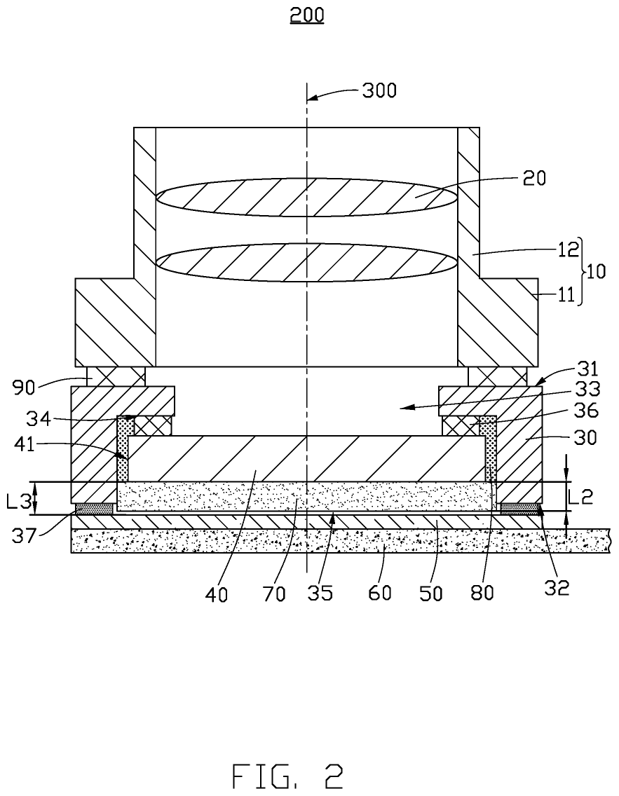

FIG. 3 is a diagram of an embodiment of an electronic device according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

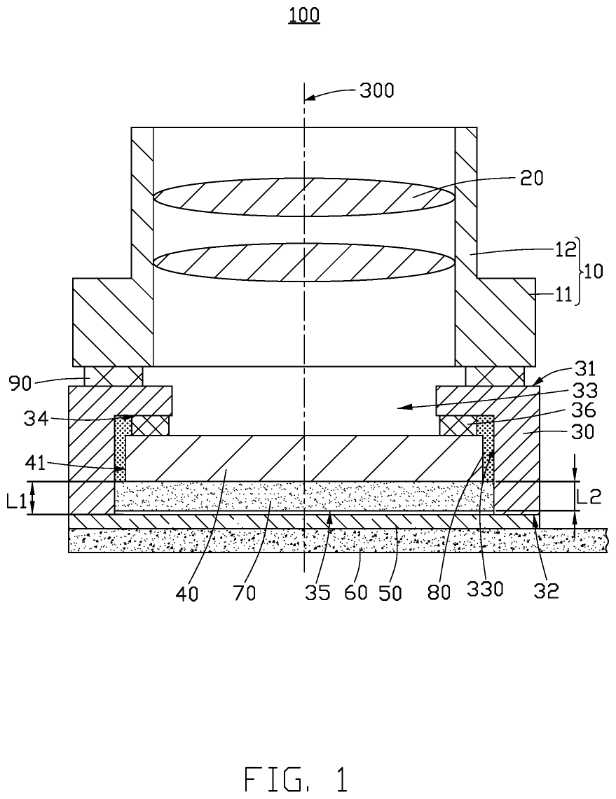

FIG. 1 illustrates a first embodiment of a lens module 100. The lens module 100 includes a holder 10, at least one lens 20 received in the holder 10, a base 30, a sensor 40, an anisotropic conductive film 50, a flexible circuit board 60, and a filling member 70.

The base 30 includes a first surface 31, a second surface 32 facing away from the first surface 31, and a receiving hole 33 penetrating the first surface 31 and the second surface 32. The receiving hole 33 is a stepped hole, and an inner wall 330 defining the receiving hole 33 includes a stepped portion 34. The sensor 40 is received in the receiving hole 33 and abuts the stepped portion 34. An end of the holder 10 is connected to the first surface 31. The flexible circuit board 60 is connected to the second surface 32 through the anisotropic conductive film 50. The filling member 70 is arranged at a side of the sensor 40 facing away from the stepped portion 34 and received in the receiving hole 33. Along a direction of an optical axis 300 of the lens module 100, a distance L1 between the side of the sensor 40 facing away from the stepped portion 34 and a side of the anisotropic conductive film 50 facing the second surface 32 is defined as a first value, a thickness L2 of the filling member 70 is defined as a second value, a ratio of L2 to L1 is in a range of 0.8 to 1.

In at least one embodiment, the ratio of L2 to L1 may be one of 0.8, 0.81, 0.82, 0.83, 0.84, 0.85, 0.86, 0.87, 0.88, 0.89, 0.9, 0.91, 0.92, 0.93, 0.94, 0.95, 0.96, 0.97, 0.98, 0.99, and 1.

A gap 35 between the side of the sensor 40 facing away from the stepped portion 34 and the anisotropic conductive film 50 can be reduced to more than 80% by arranging the filling member 70 between the side of the sensor 40 facing away from the stepped portion 34 and the anisotropic conductive film 50, thereby reducing air in the gap 35. Therefore, when the assembled lens module 100 is subjected to high temperature and high pressure or undergoes a destructive test, a large amount of air in the gap 35 is prevented from being thermally expanded to deform the flexible circuit board 60, thereby improving a reliability of the lens module 100.

In at least one embodiment, the holder 10 may include a substrate 11 and a mounting portion 12 fixed on an end of the substrate 11. The substrate 11 may have a hollow rectangular parallelepiped shape. The mounting portion 12 may have a hollow cylindrical shape. The substrate 11 communicates with the mounting portion 12 to be used for light transmission. The at least one lens 20 is installed in the mounting portion 12. An end of the substrate 11 facing away from the mounting portion 12 is connected to the first surface 31 of the base 30.

In at least one embodiment, the first surface 31 of the base 30 may be bonded to the substrate 11 of the holder 10 through a second glue 90. The second glue 90 may be made of thermosetting resin. In this way, an accuracy of the connection between the base 30 and the holder 10 can be ensured, so that a central axis of the receiving hole 33 coincides with the optical axis 300 of the lens module 100, an imaging quality of the lens module 100 can be ensured.

In at least one embodiment, the second glue 90 may be made of epoxy resin.

The at least one lens 20 is configured for modulate the ambient light and project the ambient light to the sensor 40. In at least one embodiment, the number of the lens 20 is two. In at least one embodiment, the number of the lens 20 may be one, three, four or more.

In at least one embodiment, the substrate 11 may be a hollow cylinder or other hollow columnar structure.

In at least one embodiment, the base 30 may be made of ceramic, and at least one wiring line (not shown) for transmitting electric energy and electrical signals is arranged on the base 30. That is, the base 30 may be a rigid printed circuit board. In at least one embodiment, the base 30 may be roughly in a shape of a hollow rectangular parallelepiped. Along the direction of the optical axis 300 of the lens module 100, a cross section of the receiving hole 33 is rectangular. At least one wiring line (not shown) is arranged on the stepped portion 34 to be electrically connected to the sensor 40.

The base 30 may be made of alumina ceramic or aluminum ceramic.

The sensor 40 may be roughly rectangular parallelepiped. The sensor 40 is configured for detect the ambient light passing through the at least one lens 20, convert the detected ambient light signal into an electrical signal, and transmit the electrical signal to an external circuit. The external circuit may be the flexible circuit board 60 or a processor (not shown).

In at least one embodiment, the sensor 40 may be a CCD (Charge Coupled Device) or a CMOS (Complementary Metal Oxide Semiconductor).

In at least one embodiment, a plurality of first electrical connectors 36 are arranged on the stepped portion 34 and electrically connected to the at least one wiring line on the base 30. The sensor 40 is electrically connected to the plurality of first electrical connectors 36.

Each of the plurality of first electrical connectors 36 may be a gold ball, a tin ball or a silver glue.

The sensor 40 includes an outside wall 41 connected to the side of the sensor 40 facing away from the stepped portion 34 and a side of the sensor 40 facing the stepped portion 34. A first glue 80 is filled between the outside wall 41 of the sensor 40 and the inner wall 330 defining the receiving hole 33 to fix the sensor 40 in the receiving hole 33, thereby preventing the sensor 40 from loosening in the receiving hole 33.

In at least one embodiment, the first glue 80 may be made of epoxy resin.

The base 30 may be switched to an external circuit through the flexible circuit board 60, that is, the ambient light signal detected by the sensor 40 may be transmitted to the external circuit through the flexible circuit board 60.

The anisotropic conductive film 50 is attached between the base 30 and the flexible circuit board 60, and the anisotropic conductive film 50 is electrically connected the flexible circuit board 60 and the at least one wiring line on the base 30 along the direction of the optical axis 300.

In at least one embodiment, the anisotropic conductive film 50 may be attached to the second surface 32 of the base 30 with a pressure of 20 N through a thermal head (not shown) and a buffer (not shown). Then, the flexible circuit board 60 is pressed onto the side of the anisotropic conductive film 50 facing away from the base 30.

In at least one embodiment, the distance L1 may be in a range of 0.12 mm to 0.18 mm, and the thickness L2 may be in a range of 0.095 mm to 0.15 mm.

In at least one embodiment, the distance L1 may be 0.15 mm, and the thickness L2 may be one of 0.12 mm, 0.125 m, 0.13 mm, 0.135 mm, 0.14 mm, 0.145 mm, and 0.15 mm. That is, the ratio of L2 to L1 may be one of 0.8, 0.833, 0.867, 0.9, 0.933, 0.967, and 1.

In at least one embodiment, the distance L1 may be 0.12 m, 0.13 mm, 0.14 mm, 0.16 mm, 0.17 mm, or 0.18 mm.

A hardness of the filling member 70 is less than or equal to 85. In this way, it can be ensured that the filling member 70 will not damage the sensor 40 and the anisotropic conductive film 50 due to too high hardness.

In at least one embodiment, the filling member 70 may be made of a flexible material, such as silica gel or rubber.

In at least one embodiment, the filling member 70 may be made of a thermally conductive material. When the lens module 100 undergoes a high temperature and high pressure test, the filling member 70, the filling member 70 can conduct heat, thereby reducing a temperature of the air in the gap 35 and a degree of a thermal expansion of the air in the gap 35.

The filling member 70 may be made of thermally conductive silica gel.

FIG. 1 illustrates a second embodiment of a lens module 200. A structure of the lens module 200 is roughly similar to a structure of the lens module 100 of the first embodiment. Different from the first embodiment in that a plurality of second electrical connectors 37 is arranged on the second surface 32 of the base 30 and electrically connected to the at least one wiring line on the base 30. The anisotropic conductive film 50 is electrically connected to the plurality of second electrical connectors 37. Along a direction of an optical axis 300 of the lens module 200, a distance L3 between the side of the sensor 40 facing away from the stepped portion 34 and a side of the plurality of second electrical connectors 37 facing the anisotropic conductive film 50 is defined as a third value, a ratio of L2 to L3 is in a range of 0.8 to 1.

Each of the plurality of second electrical connectors 37 may be made of conductive material. In at least one embodiment, each of the plurality of second electrical connectors 37 may be a copper pad.

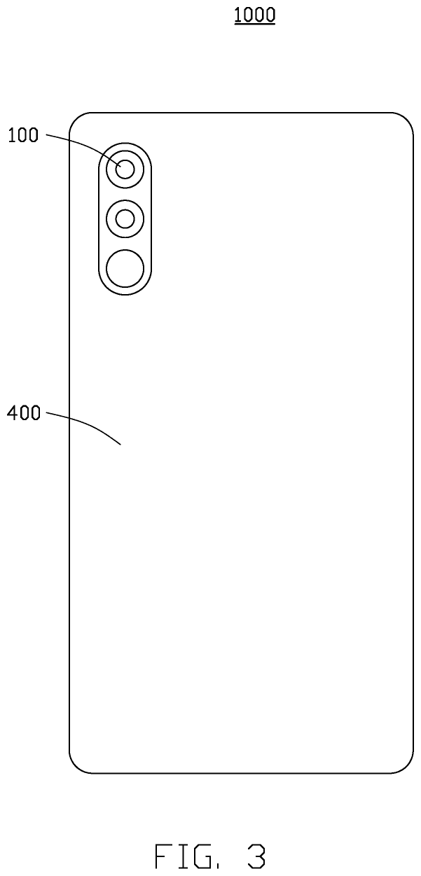

FIG. 3 illustrates an embodiment of an electronic device 1000 including the above lens module (such as 100 or 200). The electronic device 1000 may be, but not limited to, a mobile phone, a wearable device, a computer device, a vehicle or a monitoring device.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A lens module comprising:
a holder;
at least one lens received in the holder;
a base;
a sensor;
an anisotropic conductive film;
a flexible circuit board; and
a filling member;
wherein the base comprises a first surface, a second surface facing away from the first surface, and a receiving hole penetrating the first surface and the second surface; the receiving hole is a stepped hole, and an inner wall defining the receiving hole comprises a stepped portion; the sensor is received in the receiving hole and abuts the stepped portion, an end of the holder is connected to the first surface, the flexible circuit board is connected to the second surface through the anisotropic conductive film; the filling member is arranged at a side of the sensor facing away from the stepped portion and received in the receiving hole; along a direction of an optical axis of the lens module, a distance between the side of the sensor facing away from the stepped portion and a side of the anisotropic conductive film facing the second surface is defined as a first value, a thickness of the filling member is defined as a second value, a ratio of the second value to the first value is in a range of 0.8 to 1.

2. The lens module of claim 1, wherein a hardness of the filling member is less than or equal to 85.

3. The lens module of claim 2, wherein the filling member is made of a flexible material.

4. The lens module of claim 3, wherein the filling member is made of thermally conductive silica gel.

5. The lens module of claim 1, wherein a plurality of first electrical connectors arranged on the stepped portion, and the sensor is electrically connected to the plurality of first electrical connectors.

6. The lens module of claim 1, wherein the sensor comprises an outside wall connected to the side of the sensor facing away from the stepped portion and a side of the sensor facing the stepped portion, a first glue is filled between the outside wall of the sensor and the inner wall defining the receiving hole to fix the sensor in the receiving hole.

7. The lens module of claim 1, wherein a plurality of second electrical connectors is arranged on the second surface of the base, the anisotropic conductive film is electrically connected to the plurality of second electrical connectors; along the direction of an optical axis of the lens module, a distance between the side of the sensor facing away from the stepped portion and a side of the plurality of second electrical connectors facing the anisotropic conductive film is defined as a third value, a ratio of the second value to the third value is in a range of 0.8 to 1.

8. The lens module of claim 1, wherein the first surface of the base is bonded to the substrate of the holder through a second glue.

9. The lens module of claim 1, wherein a thickness of the filling member is in a range of 0.095 mm to 0.15 mm.

10. An electronic device comprising:
a lens module comprising:
a holder;
at least one lens received in the holder;
a base;
a sensor;
an anisotropic conductive film;
a flexible circuit board; and
a filling member;
wherein the base comprises a first surface, a second surface facing away from the first surface, and a receiving hole penetrating the first surface and the second surface; the receiving hole is a stepped hole, and an inner wall defining the receiving hole comprises a stepped portion; the sensor is received in the receiving hole and abuts the stepped portion, an end of the holder is connected to the first surface, the flexible circuit board is connected to the second surface through the anisotropic conductive film; the filling member is arranged at a side of the sensor facing away from the stepped portion and received in the receiving hole; along a direction of an optical axis of the lens module, a distance between the side of the sensor facing away from the stepped portion and a side of the anisotropic conductive film facing the second surface is defined as a first value, a thickness of the filling member is defined as a second value, a ratio of the second value to the first value is in a range of 0.8 to 1.

11. The electronic device of claim 10, wherein a hardness of the filling member is less than or equal to 85.

12. The electronic device of claim 11, wherein the filling member is made of a flexible material.

13. The electronic device of claim 12, wherein the filling member is made of thermally conductive silica gel.

14. The electronic device of claim 10, wherein a plurality of first electrical connectors arranged on the stepped portion, and the sensor is electrically connected to the plurality of first electrical connectors.

15. The electronic device of claim 10, wherein the sensor comprises an outside wall connected to the side of the sensor facing away from the stepped portion and a side of the sensor facing the stepped portion, a first glue is filled between the outside wall of the sensor and the inner wall defining the receiving hole to fix the sensor in the receiving hole.

16. The electronic device of claim 10, wherein a plurality of second electrical connectors is arranged on the second surface of the base, the anisotropic conductive film is electrically connected to the plurality of second electrical connectors; along the direction of an optical axis of the lens module, a distance between the side of the sensor facing away from the stepped portion and a side of the plurality of second electrical connectors facing the anisotropic conductive film is defined as a third value, a ratio of the second value to the third value is in a range of 0.8 to 1.

17. The electronic device of claim 10, wherein the first surface of the base is bonded to the substrate of the holder through a second glue.

18. The electronic device of claim 10, wherein a thickness of the filling member is in a range of 0.095 mm to 0.15 mm.
